(19) United States
(12) Patent Application Publication
(10) Pub. No.: US 2021/0300240 A1
(43) Pub. Date: Sep. 30, 2021

(54) NOTIFICATION DEVICE FOR COMMUNICATION IN VEHICLE

(71) Applicant: Honda Motor Co., Ltd., Tokyo (JP)

(72) Inventors: Masayoshi TAKORI, Saitama (JP); Yuji TSUCHIYA, Saitama (JP)

(73) Assignee: Honda Motor Co., Ltd., Tokyo (JP)

(21) Appl. No.: 17/211,888

(22) Filed: Mar. 25, 2021

(30) Foreign Application Priority Data
Mar. 27, 2020 (JP) 2020-059012

(51) Int. Cl. B60Q 1/50; B60Q 1/26

(52) U.S. Cl. CPC B60Q 1/50; B60Q 1/2619

(57) ABSTRACT

A notification device for communication in a vehicle is provided. The notification device includes a display, a housing that houses the display, a transparent outer lens that covers a front-end opening of the housing and faces the display, and a display cooling device that cools the display with cooling air, in which the display cooling device includes a cooling air passage in which the cooling air flows from the rear of the housing toward a lower portion of the housing through a front surface side of the display and is discharged from the lower portion between the housing and the outer lens.

### CROSS-REFERENCE TO RELATED APPLICATION

This application claims the priority of Japan patent application serial no. 2020-059012, filed on Mar. 27, 2020. The entirety of the above-mentioned patent application is hereby incorporated by reference herein and made a part of this specification.

### BACKGROUND

### Technical Field

The disclosure relates to a notification device for communication in a vehicle including left and right headlights at a front-end portion.

### Description of Related Art

In a vehicle such as a motor vehicle, a vehicle in which a notification device for communicating with a person outside the vehicle is installed on a grill between left and right headlights is conventionally known as described in, for example, Patent Document 1 described below.

### PATENT DOCUMENTS

[Patent Document 1] Japanese Patent Laid-Open No. 2019-26201

### SUMMARY

According to an embodiment of the disclosure, a first aspect of the disclosure is a notification device for communication in a vehicle having left and right headlights at a front-end portion and including a display disposed at the front-end portion of a vehicle between the left and right headlights and visible from a front to communicate with a person outside the vehicle according to an operation state of the vehicle, a housing fixed to the front-end portion of the vehicle and housing the display therein, a transparent outer lens covering a front-end opening of the housing and facing the display, and a display cooling device cooling the display with cooling air, in which the display cooling device includes a cooling air passage between the housing and the outer lens. The cooling air flows from a rear of the housing toward a lower portion of the housing through a front surface side of the display and is discharged from the lower portion.

According to an embodiment of the disclosure, in the notification device for communication in a vehicle according to the first aspect, an inlet of the cooling air passage may be disposed on a rear surface of the housing, and a labyrinth for preventing water from entering a display side may be provided in a vicinity of the inlet of the cooling air passage.

According to an embodiment of the disclosure, in the notification device for communication in a vehicle according to the first or second aspect, the display cooling device may include an electric cooling fan on a side lower than the display. The electric cooling fan forcibly causes the cooling air to flow in the cooling air passage.

### BRIEF DESCRIPTION OF THE DRAWINGS

FIG. 1 is a front view illustrating one embodiment of a motor vehicle on which the disclosure is implemented.

FIG. 2 is a longitudinal sectional view of a second notification device and its peripheral part (enlarged cross-sectional view along line 2-2 of FIG. 1).

FIG. 3 is a front view of a main part of the second notification device (arrow-direction view for arrow 3 in FIG. 2).

FIG. 4 is a front view of a main part illustrating some variations of display modes on a display of the second notification device.

FIG. 5 is a front view of a main part illustrating control example 1 (first half process) of the first and second notification devices immediately before a vehicle in a standby state starts moving and approaching an occupant according to a call.

FIG. 6 is a front view of a main part illustrating control example 1 (second half process).

FIG. 7 is a front view of a main part illustrating control example 2 of the first and second notification devices from the start of the approaching movement to the end of the movement with reference to a positional relationship between an occupant outside the vehicle and a calling vehicle.

FIG. 8 (12) is a front view of a main part illustrating control example 3 of the first and second notification devices at the time of starting the vehicle, and FIG. 8 (13) is a front view of a main part illustrating control example 4 of the first and second notification devices in an automatic driving state.

### DESCRIPTION OF THE EMBODIMENTS

Since the conventional notification device has a simple notification structure in which a plurality of light emitting diodes (LEDs) are arranged in a row along an outer edge of a front grill and has a simple notification mode in which display colors and blinking cycles of the LEDs are only changed, there was a problem that it could not sufficiently communicate with a person outside the vehicle.

Therefore, in order to solve the problem, for example, it is conceivable to install a display for notification at a front-end portion of the vehicle between left and right headlights. In this case, although sufficient measures against heat generation and for waterproofing need to be taken for the display, in addition to the front-end portion of the vehicle being exposed to wind and rain, there is another problem that a sufficient cooling structure and waterproof measures cannot be employed due to a space restriction.

The disclosure has been made in view of the above circumstances, and an objective of the disclosure is to provide a notification device for communication in a vehicle in which the above-described conventional problems can be solved.

An embodiment of the disclosure will be described below with reference to the accompanying drawings.

A four-wheeled motor vehicle V as a vehicle is configured so that a manual driving mode and an automatic driving mode can be switched at any time, and particularly when the automatic driving mode is selected, an automatic driving function can be exhibited. The motor vehicle V at least includes an electronic control device C as a control device installed at a suitable place of a vehicle body and capable of supporting both the manual driving and the automatic driving, sensors of various types detecting a variety of information on the motor vehicle V and the surroundings (for example, an own position of the vehicle, road conditions, pedestrians, other vehicles, and the like) required for automatic driving control, and an automatic driving operation system capable of operating drive devices of various types required for travel control of the motor vehicle V.

When the automatic driving mode is selected, the electronic control device C outputs operation commands on the basis of detection signals of the sensors to operate and control the automatic driving operation system, thereby enabling the automatic driving of the motor vehicle V. The motor vehicle V is equipped with a communication device that enables bidirectional communication with a portable mobile terminal (for example, a smartphone, a remote-control key, or the like) owned by a person outside the vehicle, and the electronic control device C can send and receive signals to and from the portable mobile terminal via the communication device.

The disclosure relates to a notification device for such a motor vehicle V capable of automatic driving to perform communication or notification to call the attention of a person outside the vehicle (for example, a driver before boarding, pedestrians, drivers of other vehicles, or the like) or the like while using a well-known conventional automatic driving technology. Therefore, in the present specification, further description regarding configurations and functions for automatic operation control of the present embodiment will be omitted, and the notification device described above will be mainly described.

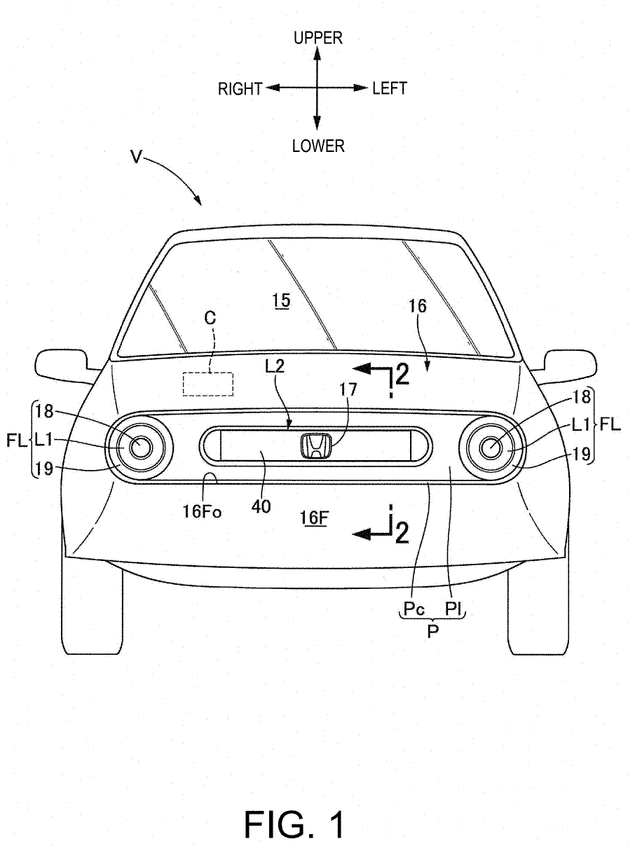

First, an outline of a front portion structure of the motor vehicle V will be described with reference to FIG. 1.

A horizontally long opening 16Fo that extends almost fully in a vehicle width direction is provided at a front-end portion 16F of a front vehicle body 16 that protrudes to a front side from a passenger compartment of the motor vehicle V, and a panel unit P that blocks the opening 16Fo is fixed to the front vehicle body 16. The panel unit P includes a notification device L2 with a horizontally long elliptical-shaped display attached at a left-right central portion, and a pair of circular left and right front combination lamp devices FL positioned on both left and right sides of the notification device L2. That is, the notification device L2 and the front combination lamp device FL are fixed to the front-end portion 16F of the front vehicle body 16 via the panel unit P.

The panel unit P is constituted by a transparent outer lens P1 that forms a main part thereof and covers the notification device L2 and the front combination lamp device FL from the front, and a mounting frame part Pc that is coupled to an outer circumferential portion of the outer lens P1 over the entire circumference to be fitted and fixed to the opening 16Fo.

A round headlight 18, one of left and right first notification devices L1 that concentrically surrounds the headlight 18 in a front view, and one of left and right ring-shaped auxiliary lights 19 that concentrically surrounds the first notification device L1 in a front view are integrated into a unit to form each of the front combination lamp devices FL. Similarly to a normal headlight, the headlight 18 is configured by a high/low switchable round light (for example, a projector lamp or the like) that brightly illuminates the front of the vehicle. Also, the first notification device L1 includes a ring-shaped light emitting unit that surrounds the headlight 18 and whose light emitting region is variable.

Also, the auxiliary light 19 functions as an auxiliary lighting device (a direction indicator lamp, a side-marker lamp, a daytime traveling lamp, or the like) in addition to the headlight 18. That is, the auxiliary light 19 is always turned on with a brightness to such an extent that it does not dazzle people, for example, during daytime traveling of the motor vehicle V (including during traveling in automatic driving to be described later), also blinks as a direction indicator lamp when a blinker is operated, and is turned on as a side-marker lamp at night.

Thus, the left and right headlights 18 are an example of left and right round lights surrounded by the first notification devices L1, and the left and right auxiliary lights 19 are an example of left and right second lights disposed on an outward side of the first notification devices L1.

As a plurality of notification units capable of changing notification modes according to a vehicle operation state for communicating with a person outside the vehicle, the four-wheeled motor vehicle V of the present embodiment includes the ring-shaped first notification device L1 disposed around the headlight 18 to surround it, and the second notification device L2 with an attached display 40 disposed at the front-end portion 16F of the motor vehicle V between the left and right headlights 18. Particularly, the second notification device L2 constitutes the notification device of the disclosure.

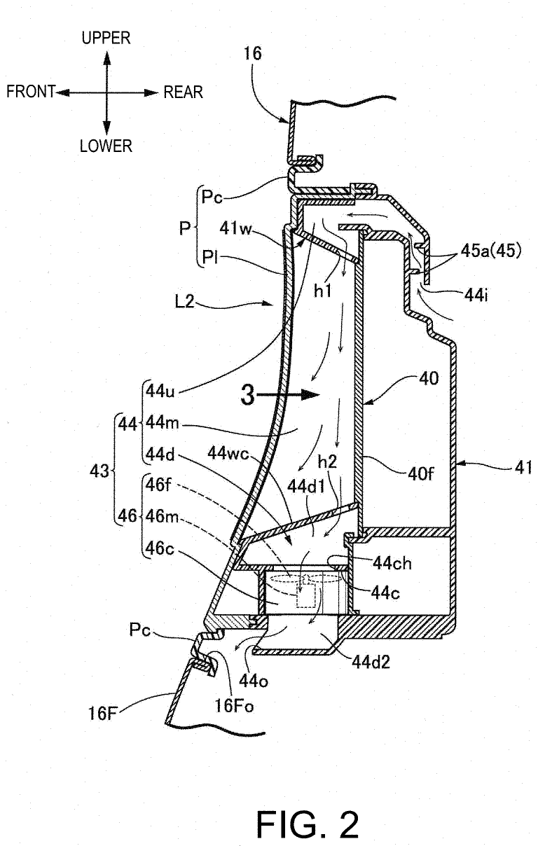

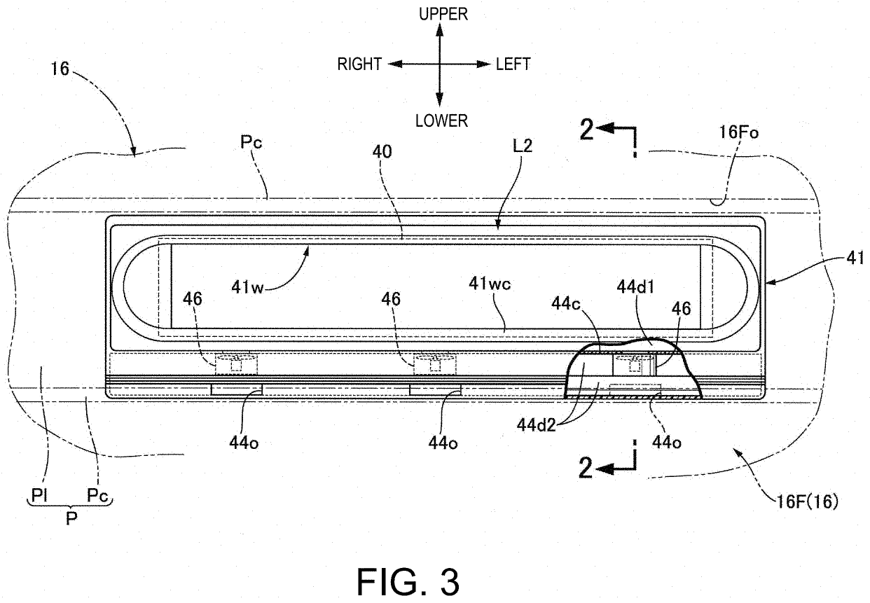

Next, an example of the second notification device L2 will be described with reference to FIGS. 2 to 4.

The second notification device L2 is constituted by the display 40 visible from the front of the vehicle, a horizontally long rectangular housing 41 that is flat in a front-rear direction disposed at the front-end portion 16F of the motor vehicle V between the left and right front combination lamp devices FL and housing the display 40 therein, the outer lens P1 of the panel unit P that covers a front-end opening of the housing 41 and faces a display surface 40f of the display 40, and a display cooling device 43 that cools the display 40 with cooling air.

A horizontally long rectangular window hole part 41w serving as a viewing window of the display 40 is provided on a front-end wall part of the housing 41. In the window hole part 41w, a chamfered edge 41wc is applied over the entire circumference in an inner circumferential portion thereof, and an outer circumferential edge thereof is rimmed in a horizontally long elliptical shape in a front view.

Further, the housing 41 of the embodiment is fitted and fixed to a rear extension part of the outer lens P1 of the panel unit P, but instead of or in addition to this fixing structure, the housing 41 may be fixed to the front vehicle body 16 using a fixing method (not illustrated) without the panel unit P interposed.

The display 40 is a liquid crystal display and is formed in a plate shape that is a horizontally long rectangular shape and is flat in a front-rear direction. A part of the display surface 40f (left-right central portion in the illustrated example) of the display 40 is covered with a decorative emblem 17 joined (for example, affixed) to the outer lens P1. Further, since the emblem 17 is not related to notification, description thereof may be omitted.

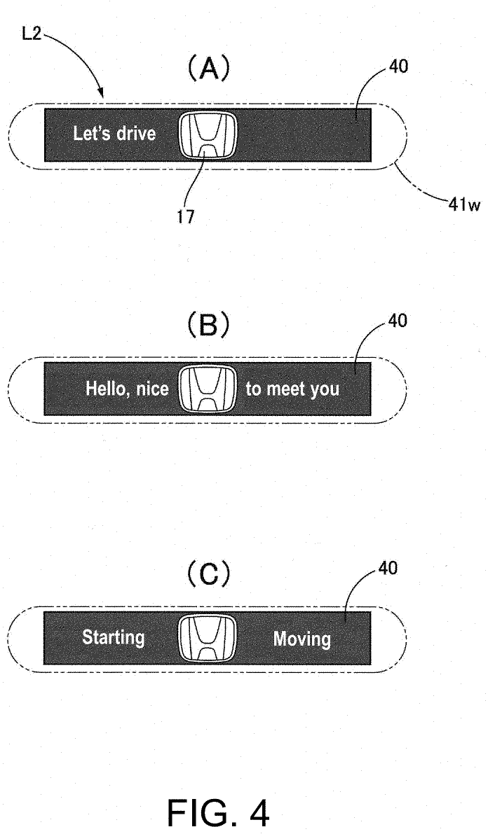

Thus, the second notification device L2 is connected to the electronic control device C via a wiring (not illustrated), and the electronic control device C can control display content of the display 40 to be changed in order to communicate with a person outside the vehicle according to an operation state of the motor vehicle V. The display content may be, for example, a message in Japanese characters only or a message in which English characters are also written as illustrated in FIG. 4.

In a housing internal space between the housing 41 and the outer lens P1, the display cooling device 43 includes a cooling air passage 44 in which cooling air flows from the rear of the housing 41 toward a lower portion of the housing 41 through the front surface (that is, the display surface 400 side of the display 40.

An inlet 44i of the cooling air passage 44 is provided on a rear surface of the housing 41 facing the inside of a hood of the front vehicle body 16, and a labyrinth 45 for preventing water from entering a downstream side (that is, the display 40 side) is provided at the cooling air passage 44 in the vicinity of the inlet 44i. The labyrinth 45 is constituted by a plurality of baffle plates 45a that, for example, alternately protrude on an inner surface of a passage wall of the cooling air passage 44.

The cooling air passage 44 sequentially includes an upper passage 44u, in which the cooling air that has passed through the labyrinth 45 flows in and which extends in a left-right direction, an intermediate passage 44m in which the cooling air that has passed through the upper passage 44u flows in through a plurality of upper throttle holes h1 aligned on the left and right sides and which extends in the left-right direction, and a lower passage 44d in which the cooling air (a plurality of air flows) that has passed through the intermediate passage 44m flows in through a plurality of lower throttle holes h2 aligned on the left and right sides and which extends in the left-right direction. The display surface 40f of the display 40 faces the intermediate passage 44m and is cooled by the cooling air flowing downward there.

Also, the lower passage 44d is partitioned into an upper chamber 44d1 and a lower chamber 44d2 which extend long in the left-right direction by a partition wall 44c that partitions an internal space thereof vertically. The partition wall 44c includes a plurality (a left and right pair in the illustrated example) of through holes 44ch that allow the upper chamber 44d1 and the lower chamber 44d2 to communicate with each other to narrow a space therebetween, and a plurality of cooling fan units 46 to be described later are disposed in the lower chamber 44d2 at intervals from each other to face the through holes 44ch. Also, a plurality of cooling air outlets 44o for allowing the lower chamber 44d2 to communicate with the inside of the hood of the front vehicle body 16 are provided at intervals from each other in a front wall of the lower chamber 44d2.

The display cooling device 43 includes the cooling fan units 46 constituting an electric cooling fan that forcibly causes the cooling air to flow in the cooling air passage 44 on a side lower than the display 40. The fan unit 46 is constituted by incorporating a motor 46m and a fan main body 46f in a cylindrical unit case 46c that opens upward and downward, and the unit case 46c is housed in the lower chamber 44d2 just below the partition wall 44c and fixed to the housing 41 using a fixing method (not illustrated). Then, fan rotating surfaces of the cooling fan units 46 are disposed to face the through hole 44ch.

Therefore, when the cooling fan units 46 are rotationally driven, air on an upstream side is suctioned by the cooling fan units 46 through the through holes 44ch and is forcibly discharged to the outside of the housing 41 from a downstream side of the cooling fan units 46, accordingly, from the cooling air outlets 44o.

Thus, the cooling fan units 46 are operated and controlled by the electronic control device C, that is, rotationally driven according to an operation state of the motor vehicle V (particularly, an operation state of the display 40) to forcibly circulate the cooling air in the cooling air passage 44 from the inlet 44i to the outlets 44o. Thereby, the display 40 is appropriately cooled by the cooling air even when heat is generated according to the operation.

Next, an operation of the embodiment will be described.

A control program for light emission control or display control of the first and second notification devices L1 and L2 according to an operation state of the motor vehicle V is stored in advance in the on-board electronic control device C. Then, when the motor vehicle V is in a specific operation state in which the motor vehicle V should communicate with or provide a notification to a person outside the vehicle as will be described below, the electronic control device C can control the first and second notification devices L1 and L2 so that light emission modes or display modes are changed according to content of the communication or notification.

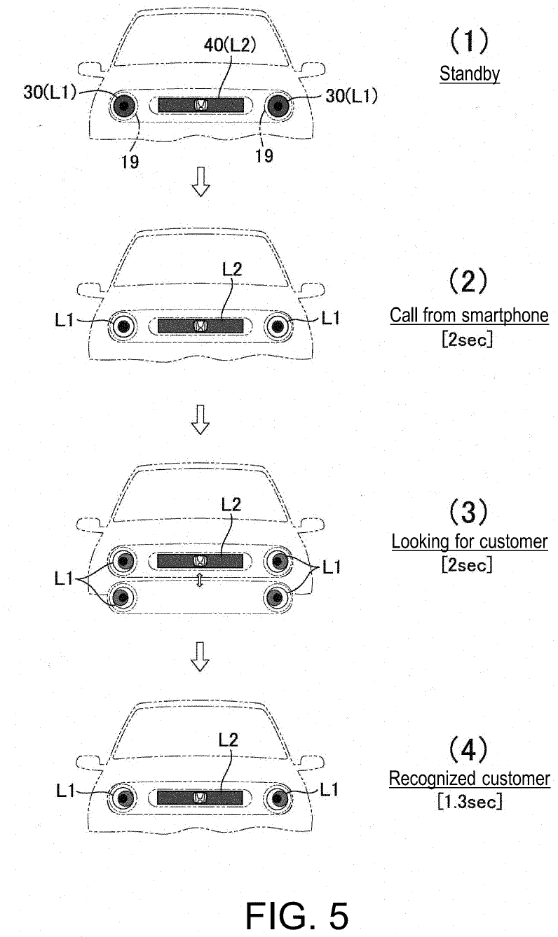

More specifically, from a standby and stop state of the motor vehicle V to a time at which the motor vehicle V moves and approaches an occupant outside the vehicle and stops at the side of the occupant according to a call operation of the occupant outside the vehicle, the electronic control device C can perform predetermined communication or a predetermined notification with respect to the occupant outside the vehicle, and furthermore, even when the motor vehicle V that has arrived at the side of the occupant outside the vehicle starts after the occupant boards the vehicle, even during traveling by automatic driving after starting, or the like, the electronic control device C can perform predetermined communication or a predetermined notification with respect to pedestrians outside the vehicle or the like. A control example of the first and second notification devices L1 and L2 for the communication therebetween described above will be described below with reference to FIGS. 5 to 8.

In these drawings, the occupant outside the vehicle who performs a call operation of the motor vehicle V is referred to as a “customer.” Also, in these drawings, a ring-shaped light emitting unit 30 of the first notification device L1 displays a light emitting state in white and a non-light-emitting state in grey.

Also, the occupant outside the vehicle who performs the above-described call operation downloads an application for linking with the motor vehicle V to his/her portable mobile terminal, for example, a smartphone, in advance to enable bidirectional communication with the motor vehicle V (specifically, the electronic control device C) with the application activated. Further, instead of the smartphone, other portable mobile terminals capable of bidirectional communication with the motor vehicle V or a dedicated remote-control key may also be used.

### Control Example 1: Control Example from when the Vehicle Receives a Call to when it Starts to Approach

In the motor vehicle V parked and standing near the occupant outside the vehicle, the first and second notification devices L1 and L2 are both in an inactive state as illustrated in FIG. 5 (1), and the headlight 18 and the auxiliary light 19 are also in a turned off state.

In such a standby state of the motor vehicle V, when the occupant outside the vehicle operates a smartphone to perform an operation to call the motor vehicle V, the electronic control device C controls light emission of the first notification device L1 so that the light emitting region has an annular shape as illustrated in FIG. 5 (2) according to the operation (that is, receiving an operation signal). According to the light emission mode, the occupant outside the vehicle is notified that the motor vehicle V has recognized the call operation, and this notification state continues for a predetermined time (for example, two seconds). During this time, the second notification device L2 does not display anything.

Thereafter, the electronic control device C controls the first notification device L1 to emit light so that the light emitting region has a crescent shape and the crescent-shaped light emitting region alternately switches to the left and right as illustrated in FIG. 5 (3). This looks like a motion of looking for the occupant outside the vehicle with eyes looking left and right, and this state continues for a predetermined time (for example, two seconds), during which the electronic control device C recognizes the occupant outside the vehicle on the basis of sensor signals and positional information of the smartphone. Even in the meantime, the second notification device L2 still does not display anything.

Thereafter, as illustrated in FIG. 5 (4), the electronic control device C controls the first notification device L1 to emit light so that the crescent-shaped light emitting region is fixed to one of the left and right sides (that is, the crescent-shaped light emitting region is fixed to make it look like the eye is facing a direction in which the occupant outside the vehicle is recognized). This indicates that the motor vehicle V is recognizing and staring at the occupant outside the vehicle, and this state continues for a predetermined time (for example, 1.3 seconds). Even during this time, the second notification device L2 still does not display anything.

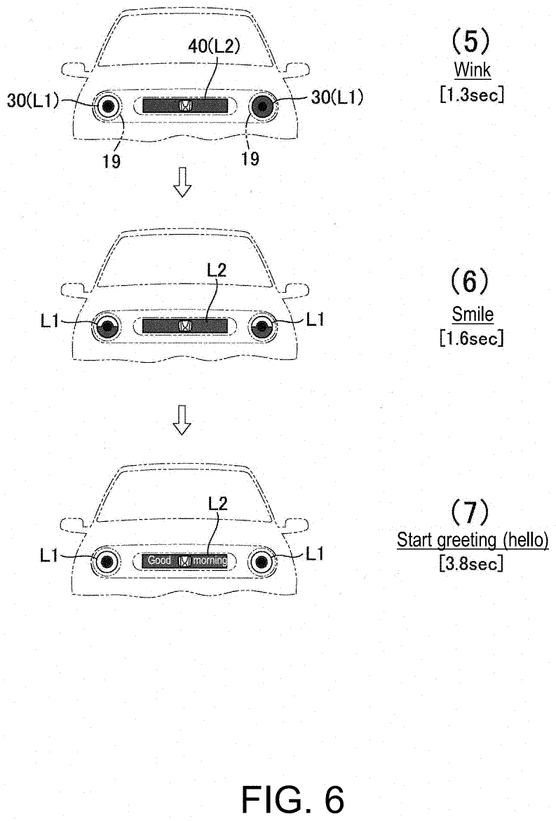

Thereafter, as illustrated in FIG. 6 (5), the electronic control device C controls the left and right first notification devices L1 so that the light emitting region of one of the left and right first notification devices L1 is fixed in an annular shape, and the other of the left and right first notification devices L1 is in a non-light-emitting state over the entire region. This looks like a winking eye motion with one eye and can give a further impression that the occupant outside the vehicle has been recognized. This state continues for a predetermined time (for example, 1.3 seconds), during which the second notification device L2 still does not display anything.

Thereafter, as illustrated in FIG. 6 (6), the electronic control device C controls the left and right notification devices L1 to emit light so that their light emitting regions both have a circular arc shape in an upper half. This looks like an eye motion of a smiling state and can be seen as if they smile recognizing the occupant outside the vehicle. This state continues for a predetermined time (for example, 1.6 seconds), during which the second notification device L2 still does not display anything.

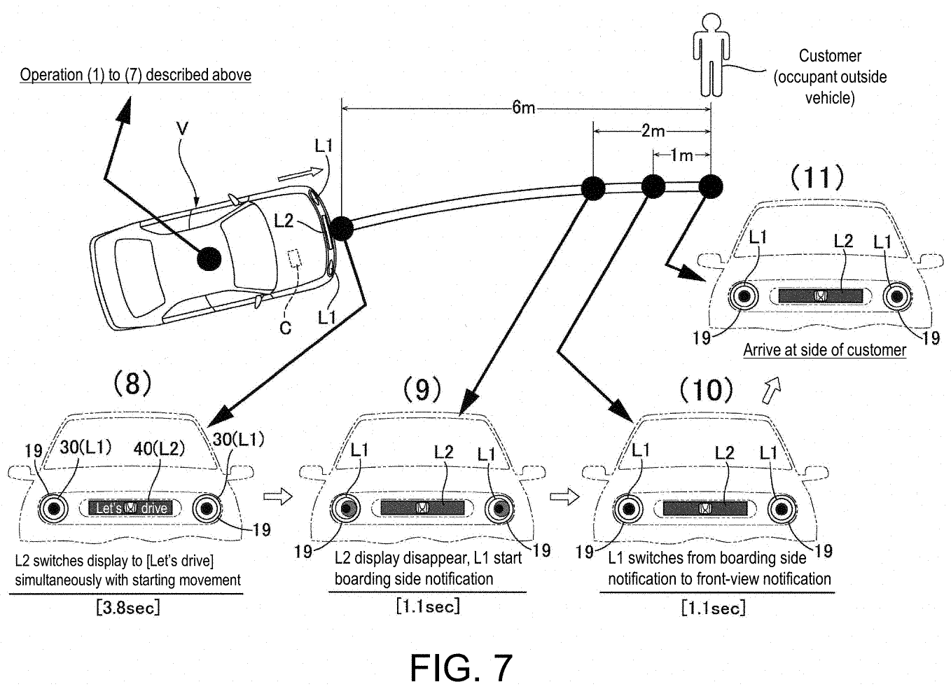

Thereafter, as illustrated in FIG. 6 (7), the electronic control device C controls the left and right first notification devices L1 to emit light so that their light emitting regions have an annular shape, and this looks like an eye motion with both eyes wide open and shining to greet the occupant outside the vehicle. At the same time, the electronic control device C operates the display 40 of the second notification device L2 to continue to display the greeting (for example, “Hello, Nice to meet you”) to the occupant outside the vehicle for a predetermined time (for example, 3.8 seconds). Then, after elapse of the predetermined time, the electronic control device C displays another message (for example, “Let's drive”) as illustrated in FIG. 7 (8).

### Control Example 2: Control Example from when the Vehicle Starts Approaching the Occupant Outside the Vehicle to when it Stops at the Side of the Occupant

Control example 2 will be described with reference to FIG. 7. Here, assuming that a distance from the motor vehicle V in a standby state to the occupant outside the vehicle is 6 m when the electronic control device C recognizes a vehicle call, an example of a relative positional relationship between the motor vehicle V and the occupant outside the vehicle at this time is illustrated in a schematic plan view of FIG. 7.

At the end of control example 1 described above, when the message illustrated in FIG. 7 (8) (for example, “Let's drive”) is displayed, the electronic control device C simultaneously starts approaching movement of the motor vehicle V to the occupant outside the vehicle, turns on the auxiliary lights 19 in an annular shape as illustrated in FIG. 7 (8) at the same time as the movement starts, and thereafter, the auxiliary lights 19 remain on as long as the motor vehicle V is in an automatic traveling state.

The motor vehicle V is automatically driven at a low speed in the process of the approaching movement from the standby position toward the occupant outside the vehicle as described above, but notification modes of the first and second notification devices L1 and L2 at this time are the same as those at the time of the movement start of the motor vehicle V, that is, the first notification device L1 continues to emit light in an annular shape, and the second notification device L2 continues to display the message “Let's drive.” Although this notification mode is continued for a predetermined first movement time (for example, 3.8 seconds), the first movement time may be set, for example, to correspond to a time required for the motor vehicle V to move at a predetermined low speed and reduce a distance to the occupant outside the vehicle to a predetermined first closest distance (for example, 2 m to the occupant outside the vehicle).

Then, when the first movement time has elapsed (that is, the distance between the motor vehicle V and the occupant outside the vehicle is reduced to the first closest distance), as illustrated in FIG. 7 (9), the electronic control device C controls the first notification device L1 to emit light so that the crescent-shaped light emitting region is fixed to one of the left and right sides as in the previous case of FIG. 5 (4), and thereby the occupant outside the vehicle is notified of a boarding side of the vehicle by making it appear that an eye faces a direction in which the occupant outside the vehicle is recognized. Simultaneously, the electronic control device C sets the second notification device L2 not to display anything.

Although the notification mode of FIG. 7 (9) is continued for a predetermined second movement time (for example, 1.1 seconds), the second movement time may be set, for example, to correspond to a time required for the motor vehicle V to move at a predetermined low speed and reduce the distance to the occupant outside the vehicle to a predetermined second closest distance (for example, 1 m to the occupant outside the vehicle). Then, when the second movement time has elapsed (that is, the distance between the motor vehicle V and the occupant outside the vehicle is reduced to the second closest distance), as illustrated in FIG. 7 (10), the electronic control device C controls the first notification device L1 to emit light so that the light emitting region has an annular shape as illustrated in FIG. 5 (2) or FIG. 6 (7) and sets the second notification device L2 to still not display anything.

Although the notification mode of FIG. 7 (10) is continued for a predetermined third movement time (for example, 1.1 seconds), the third movement time may be set, for example, to correspond to a time required for the motor vehicle V to move at a predetermined low speed and reduce the distance to the occupant outside the vehicle to zero, that is, arrive at the side of the occupant outside the vehicle. Then, when the third movement time has elapsed, as illustrated in FIG. 7 (11), the electronic control device C stops the motor vehicle V at the side of the occupant outside the vehicle, controls the first notification device L1 to emit light so that the light emitting region still has an annular shape even after the vehicle has stopped, and sets the second notification device L2 to still not display anything. Then, this notification mode continues until the occupant outside the vehicle boards the motor vehicle V or immediately before the automatic driving is started after the boarding.

In control example 2 described above, although a situation in which the first notification device L1 and the auxiliary lights 19 simultaneously emit light may occur, an inner lens 33 includes a stepped part 33s formed in the vicinity of a boundary between the first notification device L1 and the auxiliary light 19, and this makes the illumination look like an eyeline to a person outside the vehicle during the simultaneous light emission. Therefore, it is possible to avoid a situation in which the light emission mode of the ring-shaped light emitting unit 30 of the first notification device L1 is disturbed by the lighting of the auxiliary light 19 and is hard to see.

### Control Example 3: Control Example when the Vehicle Starts after the Occupant has Boarded

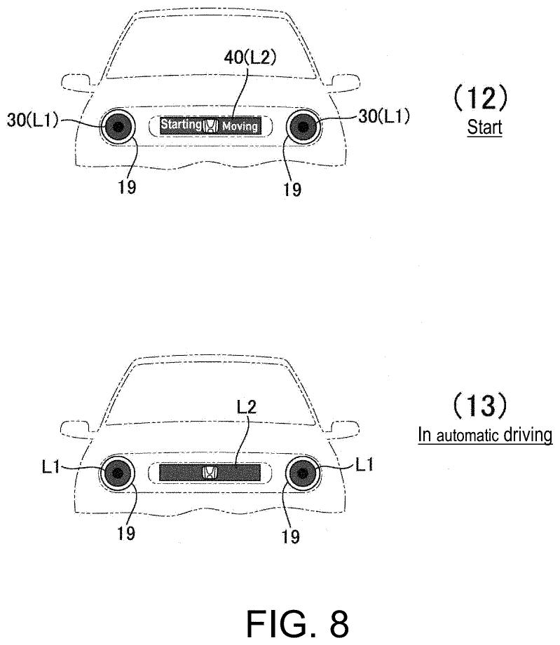

When the occupant outside the vehicle boards the motor vehicle V and performs a start command operation of the automatic driving, the motor vehicle V starts by automatic driving. According to this, as illustrated in FIG. 8 (12), the electronic control device C turns off the first notification device L1, causes the auxiliary light 19 to emit light in an annular shape as the daytime traveling lamp, and operates the second notification device L2 to display a message (for example, characters “Starting; Moving”) for calling attention of pedestrians outside the vehicle and drivers of other vehicles that the vehicle is about to start. According to such a notification mode at the time of starting, the intention of the motor vehicle V to start is clearly transferred to a third party and a strong calling attention can be given.

Although the notification at the time of starting as in control example 3 can be constantly executed unconditionally, a predetermined notification start condition may be set.

As the notification start condition, such a case of ascertaining that there is no proceeding vehicle within a predetermined range in front of the motor vehicle V, for example, within 6 m ahead (thus, there is no congestion or the like), and there is a pedestrian to be notified within a predetermined range in front of the motor vehicle V, for example, within a semicircle 14 m ahead within a predetermined time, for example, until the motor vehicle V actually starts (for example, one second before the start of the vehicle) according to the above-described driving start operation of the occupant can be conceivable as the condition. Then, when the notification under such a start condition is started, the notification will be performed only in a situation in which the notification is actually necessary.

Also, an end condition of the notification at the time of starting can be arbitrarily set. For example, it may be determined such that the notification is terminated after a predetermined time (for example, 1 second) has elapsed since the motor vehicle V actually started or after the motor vehicle V has entered a deceleration operation.

### Control Example 4: Control Example at the Time of Normal Traveling During Automatic Driving

After the motor vehicle V has started, when it is in a normal traveling state by automatic driving, although the electronic control device C puts the first notification device L1 in a non-light-emitting state and sets the second notification device L2 not to display anything (that is, no message) as illustrated in FIG. 8 (13), the electronic control device C notifies pedestrians and drivers of other vehicles of an indication that it is in an automatic driving to call attention of them by continuously turning on the auxiliary light 19 in an annular shape as the daytime traveling lamp.

As described above, in the present embodiment, when the occupant outside the vehicle calls the motor vehicle V standing by at a parking place a little away from the occupant using a smartphone or the like, the motor vehicle V can be moved to approach the occupant outside the vehicle by automatic driving, but the electronic control device C can perform communication or notification with respect to the occupant outside the vehicle according to the situation by the light emission control or the display control of the first and second notification devices L1 and L2 in the process of the vehicle call (control examples 1 and 2 described above).

Even in the process in which the vehicle V starts by automatic driving after the occupant outside the vehicle boards the vehicle V for which the call has been completed (control example 3 described above) or in the process of traveling by automatic driving after the start (control example 4 described above), the electronic control device C can perform communication or notification with respect to a person outside the vehicle (for example, pedestrians, drivers of other vehicles, or the like) according to the situation by the light emission control or the display control of the first and second notification devices L1 and L2.

Particularly, the first notification device L1 of the present embodiment includes the ring-shaped light emitting unit 30 that surrounds each of the left and right round headlights 18 of the front-end portion 16F of the vehicle in a front view and whose light emitting region is variable, the light emitting region thereof is controlled by the electronic control device C to be changed according to a vehicle operation state, particularly the change mode is made approximate to a structure and movement of eyes, and thereby the first notification device L1 can easily take a communication with a person outside the vehicle with a notification mode that just looks like making eye contact. That is, when the motor vehicle V is in an operation state in which it should communicate with a person outside the vehicle, the ring-shaped light emitting unit 30 can sufficiently and clearly communicate with a person outside the vehicle from the change in the light emitting region that is made approximate to the eye contact described above.

Also, the ring-shaped light emitting units 30 can more easily express a motion of human eyes from the change in the light emitting region of the ring-shaped light emitting units 30 by utilizing the round shape of the round headlight 18 surrounded by the ring-shaped light emitting unit 30 (that is, by making the headlight 18 look just like a black eye). Therefore, the above-described eye contact effect is enhanced, making communication easier, and the design can be made to have a sense of intimacy as a whole.

Further, since the auxiliary light 19 is disposed on an outward side of the circumference of the ring-shaped light emitting unit 30, the auxiliary light 19 which is responsible for functions such as a direction indicator lamp, a side-marker lamp, a daytime traveling lamp, and the like can be disposed in the front combination lamp devices FL without impairing the communication function of the first notification device L1.

Also, the motor vehicle V of the present embodiment includes the second notification device L2 with the display 40 attached for communicating with a person outside the vehicle at the front-end portion 16F of the front vehicle body 16 between the left and right headlights 18. Therefore, it is possible to sufficiently communicate with a person outside the vehicle through various display screens of the display 40.

In addition, the second notification device L2 includes the housing 41 that houses the display 40 therein, and the transparent outer lens P1 that covers the front-end opening of the housing 41 and faces the display 40, and the display cooling device 43 that cools the display 40 with cooling air includes the cooling air passage 44 in which the cooling air flows from the rear of the housing 41 toward the lower portion of the housing 41 through the front surface side of the display 40 and is discharged from the lower portion between the housing 41 and the outer lens P1. Thereby, the display 40 can be effectively cooled by the cooling air while rainwater is prevented from entering the display 40.

Moreover, since the inlet 44i of the cooling air passage 44 is disposed on the rear surface of the housing 41, and the labyrinth 45 for preventing water from entering the display 40 side is disposed in the vicinity of the inlet 44i of the cooling air passage 44, rainwater from the inlet 44i of the cooling air passage 44 can be effectively prevented from being mixed with the cooling air and entering the display 40 side due to a labyrinth effect.

In addition, since the display cooling device 43 includes the electric cooling fan units 46 that forcibly cause the cooling air to flow in the cooling air passage 44 on a side lower than the display 40, the cooling fan units 46 can forcibly perform circulation of the cooling air in the cooling air passage 44 and can efficiently cool the display 40. Also, since the cooling fan unit 46 is an electric type and operation control (for example, on/off control or air flow rate control) is easy by the electronic control device C, the display 40 can be efficiently cooled only when necessary. Further, since an internal space of the housing 41 has a lower portion that is formed wide in the front-rear direction and the lower chamber 44d2 of the cooling air passage 44 has a spatial room, the cooling fan unit 46 can be smoothly disposed there.

Although the embodiment of the disclosure has been described above, the disclosure is not limited thereto, and various modifications can be made in design in a range without departing from the gist of the disclosure.

For example, in the above-described embodiment, a control example in which automatic driving is performed in both the calling/moving stage in which the standing by motor vehicle V moves close to the occupant outside the vehicle according to a call operation of the occupant outside the vehicle and the starting/traveling stage in which the motor vehicle V starts and travels with the occupant outside the vehicle on board thereafter has been described, but a driving mode may be such that automatic driving is performed only in the calling/moving stage and manual driving is performed in the starting/traveling stage.

Also, in the above-described embodiment, a case in which the notification modes of the first and second notification devices L1 and L2 are controlled to be changed according to an elapsed time from the start of the approaching movement in the process in which the motor vehicle V in a standby state moves and approaches toward the occupant outside the vehicle who made the call (control example 2) has been described, but a traveling distance of the motor vehicle V from the start of the approaching movement (that is, a distance to the occupant outside the vehicle) may be measured and the notification modes of the first and second notification devices L1 and L2 may be controlled to be changed according to the distance.

Also, in the above-described embodiment, a case in which the display 40 of the second notification device L2 performs the message display in Japanese only or using characters in which Japanese and English are written together has been described, but the message display may be performed in a foreign language other than English, or a graphic display may also be employed in addition to or instead of the message display by characters.

Further, in the above-described embodiment, a case in which the left and right front combination lamp devices FL (accordingly, the first notification device L1) and the second notification device L2 positioned between the two front combination lamp devices FL are covered with the common outer lens P1 (accordingly, panel unit P) has been described, but each of the front combination lamp devices FL and the second notification device L2 may be separately covered with a plurality of outer lenses independent of each other.

According to the first aspect of the disclosure, since the notification device with the display attached for communicating with a person outside the vehicle is installed at the front-end portion of the vehicle between the left and right headlights, it is possible to sufficiently communicate with a person outside the vehicle through various display screens of the display. In addition, since the notification device includes the housing fixed to the front-end portion of the vehicle and housing the display therein, and the transparent outer lens covering the front-end opening of the housing and facing the display, and the display cooling device that cools the display with cooling air includes the cooling air passage in which the cooling air flows from the rear of the housing toward the lower portion of the housing through the front surface side of the display and is discharged from the lower portion between the housing and the outer lens, the display can be effectively cooled by the cooling air while rainwater is prevented from entering the display.

According to the second aspect of the disclosure, since the inlet of the cooling air passage is disposed on the rear surface of the housing, and the labyrinth for preventing water from entering the display side is disposed in the vicinity of the inlet of the cooling air passage, rainwater from the inlet of the cooling air passage can be effectively prevented from being mixed with the cooling air and entering the display side due to a labyrinth effect.

According to the third aspect of the disclosure, since the display cooling device includes the electric cooling fan that forcibly causes the cooling air to flow in the cooling air passage on a side lower than the display, the cooling fan can forcibly perform circulation of the cooling air in the cooling air passage and can efficiently cool the display. Also, since the cooling fan is an electric type of which operation control (for example, on/off control or air flow rate control) is easy, the display can be efficiently cooled only when necessary.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A notification device for communication in a vehicle, which is a notification device for communication in a vehicle comprising left and right headlights at a front-end portion, the notification comprising:
a display disposed at the front-end portion of the vehicle between the left and right headlights and visible from a front to communicate with a person outside the vehicle according to an operation state of the vehicle;
a housing fixed to the front-end portion of the vehicle and housing the display therein;
a transparent outer lens covering a front-end opening of the housing and facing the display; and
a display cooling device cooling the display with cooling air, wherein
the display cooling device comprises a cooling air passage between the housing and the outer lens, and the cooling air flows from a rear of the housing toward a lower portion of the housing through a front surface side of the display and is discharged from the lower portion.

2. The notification device for communication in a vehicle according to claim 1, wherein an inlet of the cooling air passage is disposed on a rear surface of the housing, and a labyrinth for preventing water from entering a display side is provided in a vicinity of the inlet of the cooling air passage.

3. The notification device for communication in a vehicle according to claim 1, wherein the display cooling device comprises an electric cooling fan on a side lower than the display, and the display cooling device forcibly causes the cooling air to flow in the cooling air passage.

4. The notification device for communication in a vehicle according to claim 2, wherein the display cooling device comprises an electric cooling fan on a side lower than the display, and the display cooling device forcibly causes the cooling air to flow in the cooling air passage.
